(19) United States
(12) Patent Application Publication
(10) Pub. No.: US 2011/0140367 A1
(43) Pub. Date: Jun. 16, 2011

(54) NOVEL COATING HAVING REDUCED STRESS AND A METHOD OF DEPOSITING THE COATING ON A SUBSTRATE

(75) Inventor: Xu Shi, Singapore (SG)

(73) Assignee: NANOFILM TECHNOLOGIES INTERNATIONAL PTE LTD, Singapore (SG)

(21) Appl. No.: 12/993,369

(22) PCT Filed: Jun. 9, 2009
(86) PCT No.: PCT/SG09/00207

§ 371 Date: Feb. 16, 2011

Related U.S. Application Data
(60) Provisional application No. 61/060,021, filed on Jun. 9, 2008.

(51) Int. Cl. F16J 9/26; B32B 7/02; C23C 14/24; C23C 14/34

(52) U.S. Cl. 277/442; 428/213; 204/192.38; 204/192.1

(57) ABSTRACT

A method of depositing a coating on a substrate, the method comprising the steps of: (a) depositing material on a substrate by performing a cathodic vacuum arc (CVA) deposition step; and (b) depositing material on a substrate by performing a physical vapor deposition (PVD) step that excludes CVA deposition wherein the thickness of the material deposited in step (a) is greater than the thickness of material deposited in step (b).

### TECHNICAL FIELD

The present invention generally relates to a novel coating having reduced stress and to a method of depositing the coating on a substrate.

### BACKGROUND

A large variety of deposition techniques are used to coat substrates. Vapor deposition technology is typically used to form thin film deposition layers in various types of applications, including microelectronic applications and heavy duty applications.

Such deposition technology can be classified in two main categories. A first category of such deposition technology is known as Chemical Vapor Deposition (CVD). CVD generally refers to deposition processes occurring due to a chemical reaction. Common examples of CVD processes include electro-deposition, epitaxy and thermal oxidation. The underlying concept behind CVD lies in the creation of solid materials as a result of direct chemical reactions occurring in the CVD environment. The reactions are typically between gaseous reactants and the solid products thus formed are slowly deposited and built up on the surface of a substrate for a pre-determined amount of time to control the thickness of said deposition.

A second category of deposition is commonly known as Physical Vapor Deposition (PVD). PVD generally refers to the deposition of solid substances occurring as a result of a physical process. The main concept underlying the PVD processes is that the deposited material is physically transferred onto the substrate surface via direct mass transfer. Typically, no chemical reaction takes place during the process and the thickness of the deposited layer is independent of chemical reaction kinetics as opposed to CVD processes.

Sputtering is a known physical deposition technique for depositing compounds on a substrate, wherein atoms, ions or molecules are ejected from a target material (also called the sputter target) by particle bombardment so that the ejected atoms or molecules accumulate on a substrate surface as a thin film. Although sputtering is a widely used technique for depositing various films on substrates, sputtering suffers from several disadvantages in that it does not render the coating suitable for a number of applications. For example, carbon films can be deposited on the substrate using sputtering techniques to provide a protective layer over the substrate. However, these protective carbon films layer obtained through sputtering are usually soft and incapable of resisting high impact stress that are encountered in heavy duty applications. Scratching and deformation of the sputtered carbon coatings are common problems that arise when these coatings are used to coat components such as automobile components which are subjected to harsh conditions.

Furthermore, as sputtering is a relatively low energy deposition process, non-uniform deposition of the ejected particles usually results, thereby causing voids to form within the deposited layers. This phenomenon is especially pronounced when sputtering is used to apply thick layers of coating onto a substrate. Consequently, the deposited material suffers from inferior adhesion to substrate surfaces, low density and reduced strength. Poor adhesion between the deposited layer and the substrate surface also lead to “chipping” problems in the finished product. Accordingly, using conventional sputtering methods to coat components having highly abrasive functionalities, such as automobile components, does not adequately prolong the lifespan of such components.

Another known physical vapor deposition technique is cathodic vapor arc deposition methods. In this method, an electric arc is used to vaporize material from a cathode target. Consequently, the resulting vaporized material condenses on a substrate to form a thin film of coating. Typically, cathodic vapor arc deposition methods are used to coat diamond like carbon (DLC) on to substrates to produce a hard protective layer of coating. Although, cathodic vapor arc deposition of DLC coatings onto substrates produces coatings that are harder and stronger than carbon coatings obtained from sputtering, cathodic vapor arc deposition of DLC coatings has its own share of drawbacks.

Due to the hard nature of DLC coatings, the internal stresses present within these coatings are high. Thus it is not practical, for instance, to apply thick layers of DLC coatings by cathodic vapor arc deposition onto substrates as the large amount internal stresses within the thick layers of coatings makes the coatings brittle and prone to cracking and breakage. Consequently, only thin layers of DLC can be appropriately applied to surfaces to increase their hardness. As a result, there is limited application of DLC such as tetrahedral amorphous carbon (TA-C) coatings. As only thin layers of DLC coatings can be applied on substrates, these coatings wear off quickly when the substrates are subjected to highly abrasive conditions. In this regard, to upkeep the protective functions and hardness of the DLC coated substrates, these substrates have to be coated periodically with DLC as part of a renewal process to prolong their lifespan. From an economical perspective, such repeated processes of coating are arduous and cost-inefficient. Hence, cathodic vapor arc deposited DLC coatings are not ideal for components that are constantly subjected to high impact stresses as well as constant abrasion, for example such as automobile parts.

There is a need to provide method of coating a substrate that overcomes or at least ameliorates one or more of the disadvantages described above.

There is a need to provide a physical vapor deposition method that is capable of producing coated substrates that are resistant to high impact as well as abrasion.

### SUMMARY

According to a first aspect, there is provided a method of depositing a coating on a substrate, the method comprising the steps of:
(a) depositing material on a substrate by performing a cathodic vacuum arc (CVA) deposition step; and
(b) depositing material on a substrate by performing a physical vapor deposition (PVD) step that excludes CVA deposition,
wherein the thickness of the material deposited in step (a) is greater than the thickness of material deposited in step (b).

Advantageously, the method utilizes at least two different ways of depositing material onto the substrate.

Advantageously, the layer deposited in step (a) is harder than that deposited in step (b), hence given that the thickness of the layer of step (a) is greater than the layer deposited in step (b), the overall hardness of the coating is high while the stress is reduced due to the layer deposited in step (b).

Advantageously, the steps (a) and (b) may be undertaken in alternating layers wherein the layer of step (b) is deposited between two layers of step (a). The intermediate layer deposited in step (b) may have less stress than the other two layers deposited in step (a). The two layers deposited in step (a) tend to be significantly harder than the layer of step (b) so that the layer of step (b) acts as a lubricating layer between the two layers deposited in step (a). Advantageously, in such an embodiment, the lubricating intermediate layer deposited in step (b), which has a smaller thickness than the base and upper layer deposited in step (a), the overall hardness of the coating is maintained while the lubricating softer intermediate layer reduces stress in the overall coating. This makes the coating ideal for use in highly abrasive environments, such as use in automotive components of an automotive engine.

The method derives the benefits offered by each of these different ways of deposition to achieve an effective coat on the substrate. More advantageously, by combining at least two different ways of deposition material on the substrate, the method produces a coat which overcomes the disadvantages inherent in a coat produced solely by each of the different deposition methods.

In one embodiment, step (a) comprises the step of depositing material on a substrate by performing a filtered cathodic vacuum arc deposition (FCVA) step. Advantageously, the FCVA technique produces coating species that are pure ions whose energy is well-defined and tunable for desired coating properties. More advantageously, FCVA produces far fewer macroparticles than conventional CVA techniques.

In another embodiment, step (b) comprises a sputtering step. Advantageously, sputtering produces a layer of coating which exhibits qualities that compliments the layer of coating that is produced by step (a).

In one embodiment, the method further comprises the step of repeating alternating steps of at least one of (a) and (b) to form subsequent layers. This allows multiple layers of coatings to be created on the substrate, increasing the overall thickness of the coating, without undesirably increasing the brittleness of the coatings. Advantageously, depending on the number of repetitions of alternating at least one of steps (a) and (b), the hardness of the coating can be customized.

In one embodiment, in step (b) the sputtering step deposits a layer of material that has a thickness dimension less than 100 times that of the layer deposited by said FCVA step of step (a). Advantageously, as the layer of material deposited by the sputtering step is very thin relative to the FCVA layer, the hardness and strength of the coating as a whole is very close to the hardness and strength of the material that is deposited by FCVA.

In one embodiment, the layer of material deposited by the FCVA step is tetrahedral amorphous carbon and the layer of material deposited by the sputtering step is amorphous carbon. Advantageously, the tetrahedral amorphous carbon imparts hardness and strength to the coating as a whole, while the sputtered amorphous carbon reduces the stress between interlayers of tetrahedral amorphous carbon. More advantageously, the alternating layers of tetrahedral amorphous carbon and amorphous carbon allow the coatings to increase in thickness without undesirable increasing the overall brittleness. Even more advantageously, the thick coating produced is capable of withstanding high impact stress and have a longer life span than conventional coatings deposited by either FCVA alone or sputtering alone.

The disclosed method may also be used to coat an automobile component. The automobile component may be selected from the group consisting of a piston ring, a piston pin, a cam shaft, a lift valve and an injection nozzle. In one embodiment, the automobile component to be coated is a piston ring or a piston pin. As piston rings and piston pins are constantly under stresses caused by repeated movements and are also prone to wear and tear, the presently disclosed method of coating can beneficially lengthen the lifespan of the piston rings and piston pins.

According to a second aspect, there is provided a piston ring or a piston pin coated by the method of the first aspect. The piston ring or piston pin coated by the disclosed method is stronger and has a higher resistance to wear and tear from repeated use as compared to piston rings or pins which have not been coated by the disclosed process.

According to a third aspect, there is provided a substrate having a coating with at least two layers, one of the layers having been deposited by physical vapor deposition (PVD) that excludes cathodic vapor arc deposition (CVA) and having less stress relative to the other layer that has been deposited by cathodic vapor arc deposition (CVA), wherein the thickness of the material deposited by CVA is greater than the thickness of material deposited by PVD that excludes CVA.

According to a fourth aspect, there is provided a piston ring or a piston pin having a coating comprising an intermediate carbon layer that is disposed between a base carbon and upper carbon layer, wherein the intermediate carbon layer has less stress relative to the base and upper carbon layers and wherein the thickness of the intermediate layer is less than the thickness of the base and upper layers.

According to a fifth aspect, there is provided a coating for an automobile component comprising an intermediate carbon layer that is disposed between a base carbon and upper carbon layer, wherein the intermediate carbon layer has less stress relative to the base and upper carbon layers, and wherein the intermediate carbon layer has less stress relative to the base and upper carbon layers and wherein the thickness of the intermediate layer is less than the thickness of the base and upper layers.

While not being bound by theory, it is believed that the intermediate layer which has less stress than the base and upper carbon layers provides a negating effect on the high stress present in the base and upper layer. Advantageously, it is believed that this reduces the overall stress of the coating as a whole, which in effect lowers of the brittleness of the coating. The intermediate carbon layer is also believed to function as a “lubricating” layer in that at an atomic level it allows some sliding to occur between the base carbon layer and the upper carbon layer. Advantageously, when in use, the availability of some leeway for movement between the layers effectively reduces the internal stress of the coating when in use.

In one embodiment, the coating has a hardness of more than 1000 Vickers. Advantageously, the coating is able to achieve a high degree of hardness whilst at the same time has lower brittleness when compared to coatings that are obtained by CVA alone.

### DEFINITIONS

The following words and terms used herein shall have the meaning indicated:

The term “hard material” as used herein refers to a material such as a pure hard metal, metal compound or diamond-like carbon, which has as a characteristic of great hardness and a high resistance to wear. The term encompasses materials having a Vickers hardness of more than 500 kg/mm², typically more than 800 kg/mm² or more than 900 kg/mm² or more than 1,000 kg/mm², for a given Vickers load of 50 mg.

The term “hard metal” as used herein refers to a metal, generally a metal such as Cr, Ti or W, which has a relatively high hardness and resistance to wear compared to a soft metal such as Al or Zn, and characterized in having a Vickers hardness of at least 500 kg/mm² for a given Vickers load of 50 milligrams. It should be realized that the more than one type of metal may be encompassed by the term, that is, the term also encompasses hard metal alloys.

The term “soft material” as used herein refers to a material such as a pure soft metal, metal compound or amorphous carbon such as graphite, which has as a characteristic of low hardness. The term encompasses materials having a Vickers hardness of less than 500 kg/mm² for a given Vickers load of 50 mg.

The term “soft metal” as used herein refers to a metal, generally a metal such as Al or Zn, which has a relatively low hardness and resistance to wear compared to a hard metal such as Cr, Ti or W, and characterized in having a Vickers hardness of less than 500 kg/mm² for a given Vickers load of 50 milligrams. It should be realized that the more than one type of metal may be encompassed by the term, that is, the term also encompasses soft metal alloys.

The term “diamond-like carbon” and abbreviation thereof, “DLC”, as used herein relates to hard carbon that is chemically similar to diamond, but with the absence of a well-defined crystal structure. Diamond-like carbon are mostly metastable amorphous material but can include a microcrystalline phase. Examples of diamond like carbon include amorphous diamond (a-D), amorphous carbon (a-C), tetrahedral amorphous carbon (ta-C) and diamond-like hydrocarbon and the like. Ta—C is the most preferred diamond like carbon.

The term “Filtered Cathodic Vacuum Arc” and abbreviation thereof “FCVA” are to be used interchangeably. A method for performing FCVA deposition is disclosed in International patent publication number WO 96/26531, which is incorporated herein in its entirety for reference. The plasma generated in a cathodic arc beam are “filtered” in that they are substantially free of macroparticles.

The term “macroparticles” refers to, in the context of this specification, contaminant particles in a cathodic arc beam. The macroparticles typically have a neutral charge and are large relative to the ions and/or atoms of the plasma. More typically, they are particles that are multi-atom clusters and are visible under an optical microscope in a deposited film using cathodic arc methods.

The term “sputtering” or “sputter deposition” describes a mechanism in which atoms are ejected from a surface of a target material upon being hit by sufficiently energetic particles. Exemplary sputtering deposition is taught by, for example, U.S. Pat. No. 4,361,472 (Morrison, Jr.) and U.S. Pat. No. 4,963,524 (Yamazaki).

The “base layer” in the context of this specification refers to the layer of material in a coating that is between an intermediate layer and a substrate. The base layer adjoins the intermediate layer but is not necessarily directly adjoined to the substrate or though it can be. The base layer may be directly in contact with a substrate or there may be another coating between the base layer and the substrate.

The “upper layer” in the context of this specification refers to the layer of coating that is directly adjacent to the intermediate layer on the opposite side to the base layer. The upper layer is not necessarily the outermost layer on the coating as other outer layers may be applied to the upper layer of the coating.

The word “substantially” does not exclude “completely” e.g. a composition which is “substantially free” from Y may be completely free from Y. Where necessary, the word “substantially” may be omitted from the definition of the invention.

Unless specified otherwise, the terms “comprising” and “comprise”, and grammatical variants thereof, are intended to represent “open” or “inclusive” language such that they include recited elements but also permit inclusion of additional, unrecited elements.

As used herein, the term “about”, in the context of concentrations of components of the formulations, typically means +/−5% of the stated value, more typically +/−4% of the stated value, more typically +/−3% of the stated value, more typically, +/−2% of the stated value, even more typically +/−1% of the stated value, and even more typically +/−0.5% of the stated value.

Throughout this disclosure, certain embodiments may be disclosed in a range format. It should be understood that the description in range format is merely for convenience and brevity and should not be construed as an inflexible limitation on the scope of the disclosed ranges. Accordingly, the description of a range should be considered to have specifically disclosed all the possible sub-ranges as well as individual numerical values within that range. For example, description of a range such as from 1 to 6 should be considered to have specifically disclosed sub-ranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

### DETAILED DISCLOSURE OF EMBODIMENTS

Exemplary, non-limiting embodiments of a method of depositing a coating on a substrate, will now be disclosed. The method comprises the steps of (a) depositing material on a substrate by performing a cathodic vacuum arc (CVA) deposition step; and (b) depositing material on a substrate by performing a physical vapor deposition (PVD) step that excludes CVA deposition. The thickness of the material deposited in step (a) is greater than the thickness of material deposited in step (b).

In one embodiment, the thickness of the material deposited in step (a) is greater than the thickness of material deposited in step (b) by a factor selected from the group consisting of at least 2 times, at least 5 times, at least 10 times, at least 25 times, at least 50 times, at least 75 times, at least 100 times.

In one embodiment, said step (a) comprises the step of depositing material on a substrate by performing a filtered cathodic vacuum arc deposition (FCVA) step. The filtered vacuum cathodic deposition step may be comprised of applying a negative voltage pulse to a substrate that is electrically conductive, such as metal. The negative voltage pulse may be ranging from about −100V to about −4500V, −200V to about −4000V, −300V to about −3000V, about −200V to about −1500V about −200V to about −1200V, from about −400V to about −800V, from about −500V to about −600V.

The negative voltage pulse may have a frequency ranging from about 1 kHz to about 50 kHz, from about 10 kHz to about 50 kHz, from about 20 kHz to about 50 kHz from about 30 kHz to about 50 kHz, from about 40 kHz to about 50 kHz. In one embodiment, the negative voltage pulse has a frequency of about 30 kHz.

The negative voltage pulse has pulse durations of about 1 μs to about 50 μs, from about 5 μs to about 45 μs, from about 10 μs to about 40 μs, from about 15 μs to about 35 μs and from about 10 μs to about 20 μs.

The physical deposition step of step (b) may be selected from the group consisting of thermal evaporation, sputtering and ion plating. In one embodiment, step (b) is a sputtering step. Preferably, step (a) is a FCVA step while step (b) is a sputtering step.

The disclosed method may also further comprise the step of repeating alternating steps of at least one of (a) and (b) to form subsequent layers. In one embodiment, steps (a) and (b) are repeated alternately until the desired coating thickness is achieved. The disclosed method may further comprise employing said sputtering and said FCVA deposition processes in alternation, in succession or a combination of both to form a coating comprised of multiple layers formed by sputtering and FCVA having the desired thickness.

Both steps (a) and (b) may be undertaken in vacuum. The pressure of the vacuum chamber at which the FCVA step is undertaken may be lower than the pressure of the vacuum chamber at which sputtering step is undertaken. In one embodiment, the pressure of the vacuum chamber at which FCVA step is undertaken is less than 1 mTorr and the pressure of the vacuum chamber at which sputtering step is undertaken is more than 1 mTorr. In one embodiment, both steps (a) and (b) can be undertaken at a temperature less than about 350° C., less than about 300° C., less than about 250° C., less than about 200° C., less than about 150° C. Preferably, both steps (a) and (b) can be undertaken at a temperature of less than about 100° C.

The material deposited by step (a) can be at least one of a hard metal, metal compound and carbon. In one embodiment, the metal compound is at least one of a hard metal oxide, a metal carbide, a metal nitride, a metal carbon nitride, a metal silicide and a metal boride. The metal compound may be comprised of oxides, carbides, nitrides, carbonitrides, silicides and borides of metals, and/or composite mixtures thereof which have a Vickers hardness of between 500 kg/mm² to more than 1,000 kg/mm² for a given Vickers load of 50 mg.

The hard metals may be chosen from the group consisting of: Scandium (Sc), Vanadium (V), Chromium (Cr), Iron (Fe), Cobalt (Co), Nickel (Ni), Yttrium (Y), Zirconium (Zr), Niobium (Nb), Molybdenum (Mo), Technetium (Tc), Rubidium (Ru), Rhodium (Rh), Palladium (Pd), Cadmium (Cd), Hafnium (Hf), Tantalum (Ta), Rhenium (Re), Osmium (Os), Iridium (Ir), Platinum (Pt), Rutherfordium (Rf), Dubnium (Db), Seaborgium (Sg), Bohrium (Bh), Hassium (Hs), tungsten (W), Meitnerium (Mt) and alloys thereof.

The material deposited by step (b) can be at least one of a soft metal, metal compound and carbon. In one embodiment, the metal compound is at least one of a metal oxide, a metal carbide, a metal nitride, a metal carbon nitride, a metal silicide and a metal boride. The metal compound may be comprised of oxides, carbides, nitrides, carbonitrides, silicides and borides of metals, and/or composite mixtures thereof which have a Vickers hardness of less than 500 kg/mm², preferably less than 100 kg/mm² for a given Vickers load of 50 mg.

The soft metals may be chosen from the group consisting of: Aluminium (Al), Zinc (Al), Copper (Cu), Lead (Pb), Tin (Sb), Gold (Au), Silver (Ag), Magnesium (Mg), Antimony (Sb), Cadmium (Cd), Thallium (Tl), Bismuth (Bi), Indium (In), Gallium (Ga), Mercury (Hg), Manganese (Mn) and alloys thereof.

The material deposited by step (b) may be a metal or metal alloy which can be classified in category that is between a soft metal and a hard metal, such as for example, titanium (Ti).

In one embodiment, the material layers that are deposited by the FCVA step and the sputtering step comprises carbon. The carbon layer deposited by the FCVA step may be relatively harder as compared to the carbon layer deposited by the sputtering step. Preferably, the carbon layer deposited by the FCVA step is tetrahedral amorphous carbon and the carbon layer deposited by the sputtering step is amorphous carbon such as graphite.

In one embodiment, the sputtering step deposits a layer of material that has a thickness dimension smaller than said FCVA step. The layer of material deposited using the sputtering step may be about 2 to 100 times, about 2 to 10 times, about 20 to 40 times, about 50 to 60 times, about 70 to 80 times or about 90 to 100 times thinner than the layer of material deposited using the FCVA step.

The material layer deposited by the sputtering step may be less than 100 nanometers, less than 80 nanometers, less than 60 nanometers, less than 50 nanometers, less than 40 nanometers, less than 30 nanometers, less than 20 nanometers or less than 10 nanometers in thickness.

The material layer deposited by the FCVA step may be more than 50 nanometers, more than 100 nanometers, more than 150 nanometers, more than 200 nanometers, more than 250 nanometers, more than 300 nanometers, more than 350 nanometers, more than 400 nanometers, more than 450 nanometers or more than 500 nanometers in thickness. In one embodiment, the sputtering step deposits a material layer of thickness less than 50 nm while the FCVA step may deposit a material layer ranging from more than 300 nm in thickness.

In one embodiment, said FCVA deposition layer is deposited directly on said substrate. The FCVA deposition layer may also be deposited on a substrate that has been previously coated with a material that promotes adhesion of the coating to the substrate. The material that promotes adhesion may be any material that improves adhesion of the material layers deposited by the subsequent steps (a) and (b). For example, when the substrate is steel and the material layers deposited by subsequent steps (a) and (b) are carbon layers, the material that promotes adhesion may be titanium or chromium or combinations thereof. In one embodiment, the material layer may be a metal layer that is deposited between the substrate and the coating. The material layer that promotes adhesion may be first coated on the substrate by a physical deposition step selected from the group consisting of thermal evaporation, sputtering, ion plating, cathodic arc vapor deposition and filtered cathodic vacuum arc (FCVA). The material layer that promotes adhesion may have a thickness from about 50 nanometers to about 500 nanometers, from about 150 nanometers to about 450 nanometers, from about 200 nanometers to about 400 nanometers, from about 250 nanometers to about 350 nanometers or from about 300 nanometers to about 500 nanometers. In one embodiment, the material layer that promotes adhesion is deposited on at a voltage bias selected from the group consisting of about 800V, about 1000V, about 1200V and about 1500V.

The material layers deposited by the subsequent steps (a) and (b) may also be deposited on a seed layer which is adjacent to the material that promotes adhesion. The seed layer may comprise of carbon which may be first coated on the substrate by a physical deposition step selected from the group consisting of thermal evaporation, sputtering, ion plating, cathodic arc vapor deposition and filtered cathodic vacuum arc (FCVA).

The seed layer may have a thickness from about 50 nanometers to about 300 nanometers, from about 100 nanometers to about 250 nanometers, from about 120 nanometers to about 200 nanometers or from about 150 nanometers to about 180. In one embodiment, the seed layer bias is selected from the group consisting of about 80V, about 100V, about 120 V, about 200V, about 200/1200V and about 1200V. The seed layer may also be optional if the layer of material that promotes adhesion as described above is already present.

In one embodiment, the final coating achieved by the disclosed method may comprise at least two layers, one of the layers having been deposited by physical vapor deposition (PVD) that excludes cathodic vapor deposition (CVD) as described above and having less stress relative to the other layer that has been deposited by cathodic vapor deposition (CVD) as described above. The two layers described above may also form a repeating unit such that the coating comprises a plurality of these repeating units. The entire thickness of these repeating layers can be termed as the bulk layer. In one embodiment, the FCVA bias of the bulk layer is selected from the group consisting of about 200V, about 500V, about 800V, about 1200V and about 600/1200V.

In one embodiment, the coating comprises three layers, including an intermediate layer that is disposed between a base and upper layer, wherein the intermediate layer has less stress relative to the base and upper layers. The thickness of the intermediate layer is less than the thickness of either the base or upper layers.

The upper and base layers may have a thickness dimension which is greater than the thickness dimension of the intermediate layer, which is at least 2 times, preferably at least 5 times, preferably at least 10 times, preferably at least 25 times, preferably at least 50 times, preferably at least 75 times, preferably at least 100 times.

In one embodiment, the upper and base layers have a thickness dimension which is greater than the thickness dimension of the intermediate layer in the range selected from the group consisting of 2 to 100 times, about 2 to 10 times, about 20 to 40 times, about 50 to 60 times, about 70 to 80 times, about 90 to 100 times, about 10 to 200 times, about 25 to 200 times, about 50 to 200 times and about 100 to 200 times.

The intermediate layer, base and upper layer may be carbon layers. The base carbon and upper carbon layer each may have a stress of more than 1 GPa, while the intermediate carbon layer has a stress of less than 20%, more preferably less than 10% of the stress of base carbon layer or the upper carbon layer.

In one embodiment, the intermediate carbon layer is an amorphous carbon layer such as graphite while the base and upper carbon layers are tetrahedral amorphous carbon. The intermediate layer, base and upper layer may also form a repeating unit such that the coating comprises a plurality of these repeating units. The entire thickness of these repeating layers can be termed as the bulk layer. In one embodiment, the FCVA bias of the bulk layer is selected from the group consisting of about 200V, about 500V, about 800V, about 1200V and about 600/1200V.

The final coating achieved by the disclosed method may have a Vickers hardness ranging from about 500 kg/mm² to about 2000 kg/mm², from about 500 to about 1800 kg/mm², from about 500 to about 1,500 kg/mm², from about 500 to about 1300 kg/mm², from about 500 to 1100 kg/mm², from about 500 to about 1000 kg/mm², from about 500 to about 900 kg/mm², from about 500 to about 800 kg/mm², for a Vickers load of 50 milligrams. Advantageously, the disclosed deposited material may have a Vickers hardness of at least about 1000 kg/mm², conferring the deposited material with wear resistance and durability. The coating may also have a hardness of more than 1000 Vickers, more than 1200 Vickers, more than 1400 Vickers, more than 1500 Vickers or more than 2000 Vickers.

The final coating achieved by the disclosed method may have a stress of less than 0.5 GPa, less than 0.3 GPa or less than 0.2 GPa.

The thickness of the final coating achieved may be more than 1 micron, more than 3 microns, more than 4 microns, more than 5 microns, more than 10 microns, more than 15 microns or more than 20 microns.

In one embodiment, the coating comprises an intermediate layer of amorphous carbon disposed between a base and upper layers of tetrahedral amorphous carbon, wherein the base and upper layers of tetrahedral amorphous carbon are at least 50 times, preferably 100 times, the thickness dimension of the amorphous carbon intermediate layer, wherein the hardness of the coating is at least 1000 Vickers.

The disclosed method may also be used to coat an automobile component selected from the group consisting of a piston ring, a piston pin, a cam shaft, a lift valve and an injection nozzle.

### BRIEF DESCRIPTION OF DRAWING

The accompanying drawing illustrates a disclosed embodiment and serves to explain the principles of the disclosed embodiment. It is to be understood, however, that the drawing is designed for purposes of illustration only, and not as a definition of the limits of the invention.

FIG. 1 is a schematic diagram of the layer structure of the coating obtained according to one embodiment of the method disclosed herein.

FIG. 2a is a schematic diagram of the pin on disk test setup disclosed below.

FIG. 2b are photographs showing the physical conditions of the coated surfaces having pin on disk test ratings from 1 to 6.

FIG. 3 are schematic drawings showing the physical conditions of the coated surfaces having adhesion level test ratings from 1 to 6.

FIG. 4a-4d are graphical representations of the results of Table 1A described below.

FIG. 4e-4h are graphical representations of the results of Table 1B described below.

FIG. 5a-5c are graphical representations of the results of Table 2A described below.

FIG. 5d-5f are graphical representations of the results of Table 2B described below.

FIG. 6a-6d are graphical representations of the results of Table 3A described below.

FIG. 6e-6g are graphical representations of the results of Table 3B described below.

FIG. 7a-7d are graphical representations of the results of Table 4A described below.

FIG. 7e-7g are graphical representations of the results of Table 4B described below.

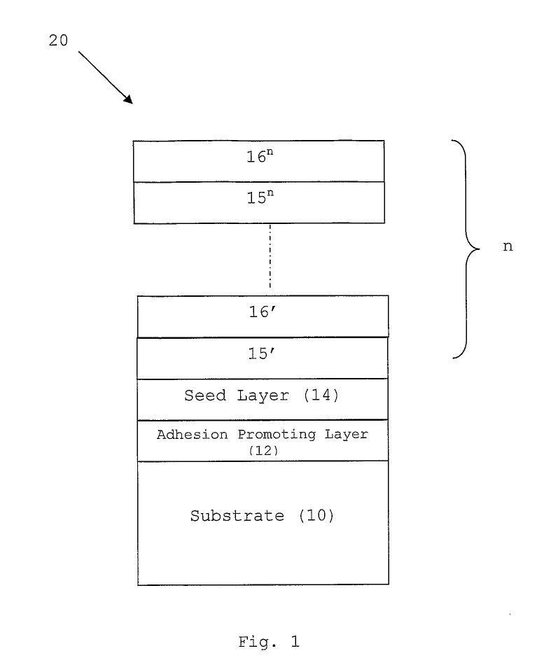

Referring to FIG. 1, there is shown a schematic diagram of the layer structure 20 of the coating obtained according to one embodiment of the method disclosed herein. The substrate layer 10 which can be a carbide substrate or a steel substrate is first coated with a layer of titanium 12, via FCVA at 1000V to a thickness of 0.25 microns. This layer of titanium 12 promotes adhesion of the subsequent layers to follow. The layer of titanium 12 is especially useful in promoting adhesion of the coating if the substrate is steel, such as high speed steel. The next layer adjacent to the titanium layer 12 is the seed layer 14. The seed layer 14 is typically a C1 seed layer (first carbon layer) that is deposited by FCVA at 120V for a steel substrate or at 1000 VP (pulse voltage) for a carbide substrate until a thickness of 0.12 microns is achieved. The seed layer 14 provides a starting point for subsequent layers of carbon layers to be deposited. This seed layer may also be optional if the titanium layer 12 is already present.

The next layer 15′ is deposited adjacent to the seed layer 14 by means of sputtering. This layer is a sputtered amorphous carbon layer such as a graphite layer and is deposited by sputtering to a thickness of less than 20 nanometers. Subsequently, another carbon layer 16′ is deposited on top of the sputtered layer 15′ by FCVA to a thickness of more than 0.35 microns. This carbon layer 16′ deposited by FCVA is tetrahedral amorphous carbon. Although the sputtered layer 15′ is shown in FIG. 1 as having a dimension that is about the same as FCVA layers (14) and (16′), this is for illustrative purposes only. The sputtered layer 15′ will have a significantly smaller thickness dimension relative to the FCVA layers (14) and (16′).

The process of sputtering and FCVA may be carried out repeatedly in an alternating manner for n number of times such that the layers 15ⁿ and 16ⁿ are top layers. The repetition number n can be chosen based on the desired overall thickness of the coating. The entire thickness from 15′ to 16ⁿ is known as the bulk layer.

### EXAMPLES

The following experiments provides comparative data showing the differences in performance of the coating when the different parameters are varied. The substrates in these experiments were coated based on the sequence shown in FIG. 1.

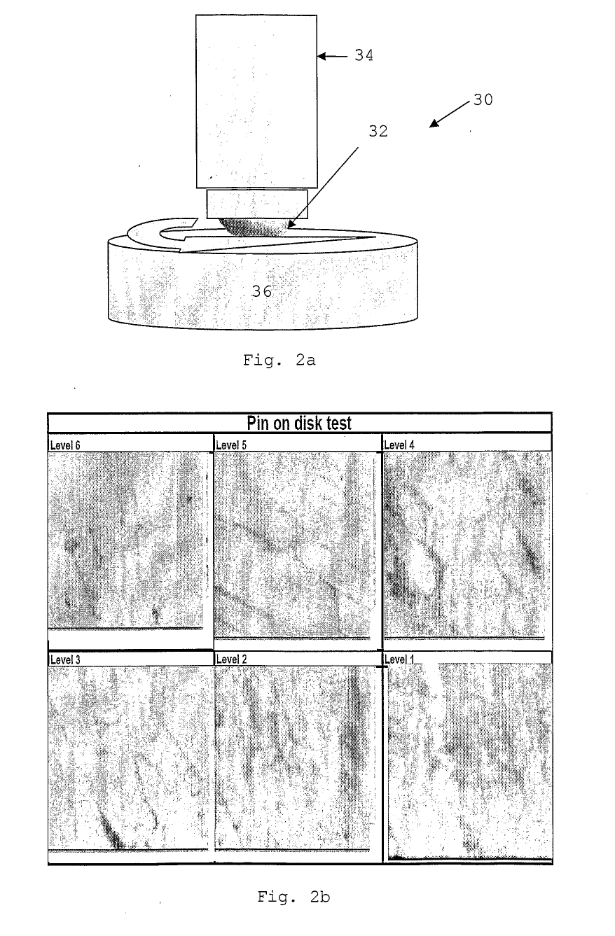

In the following experiments, the pin on disk tests (the pin on disk test setup 30 is shown in FIG. 2a) were carried out to test the film coatings' ability to withstand high impact. These tests were typically carried out by rotating a steel ball 32 of diameter 8 mm and with the appropriate loading 34 (30 kg to 50 kg), on the coated substrate 36 for a period of 5 minutes at a rotational speed of 660 rpm/min. The coatings were then given a rating from 1 to 6 with 6 being the best impact resistant ability and 1 being the worst. Exemplary photographs showing the physical conditions of the coated surfaces having pin on disk test ratings from 1 to 6 are shown FIG. 2b. For example as can be seen in FIG. 2b, the photograph with a rating of 6 shows a relatively smooth surface as compared to the photograph with a rating of 1 which clearly shows extensive flaking. Similarly, the photograph with a rating of 5 shows significantly less scratches as compared to the photograph with a rating of 2.

Similarly, the adhesion level tests by indentation were also carried out on the following experiments to test the film coatings' adhesion ability on the substrate. These tests were carried out by indenting the coated substrates with a tip of diameter 0.2±0.01 mm, having a tip angle of 120±30° at a loading force of 150 kg. The coatings were then given a rating from 1 to 6 with 6 being the best adhesion ability and 1 being the worst. Exemplary schematic drawings showing the physical conditions of the coated surfaces having adhesion level test ratings from 1 to 6 are shown FIG. 3. For example as can be seen in FIG. 3, the schematic drawing with a rating of 6 shows little or no peeling as compared to the schematic drawing with a rating of 1, which clearly shows extensive peeling indicated by the black boundary encircling a black center.

### Experiment 1

### Seed Layer & Bulk Layer Comparison on High Speed Steel

In this experiment, high speed steel (HSS) is used as the substrate. The coating process is carried out by fixing the bulk layer bias while adjusting the C1 seed layer bias. The titanium layer condition is fixed at 1000 v (0.25 microns), the bulk layer condition fixed at 600/1200 v having sputtered carbon layers each of thickness of 0.02 microns and FCVA carbon layers each of thickness of 0.35 microns. The results are tabulated in Table 1A.

TABLE 1A

| | | Adhesion | Pin on | Pin on | Critical | Hardness |
|---|---|---|---|---|---|---|
| Seed layer | | level | disk-30 kg | disk-50 kg | load | (HV) |
| 1200 | v | 4 | 3 | 2 | 14.75 | 1776 |
| 200/1200 | v | 4 | 4 | 3 | 15.91 | 1828 |
| 200 | v | 6 | 5 | 4 | 16.65 | 1947 |
| 100 | v | 6 | 6 | 5 | 18.34 | 1616 |
| 80 | v | 6 | 6 | 5 | 18.96 | 1729 |

*Critical load under 100 microns diamond tip

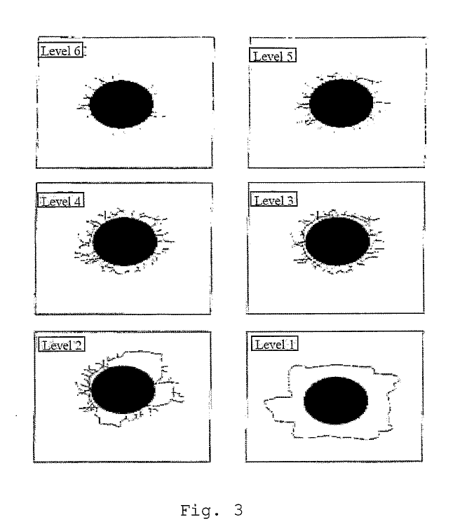

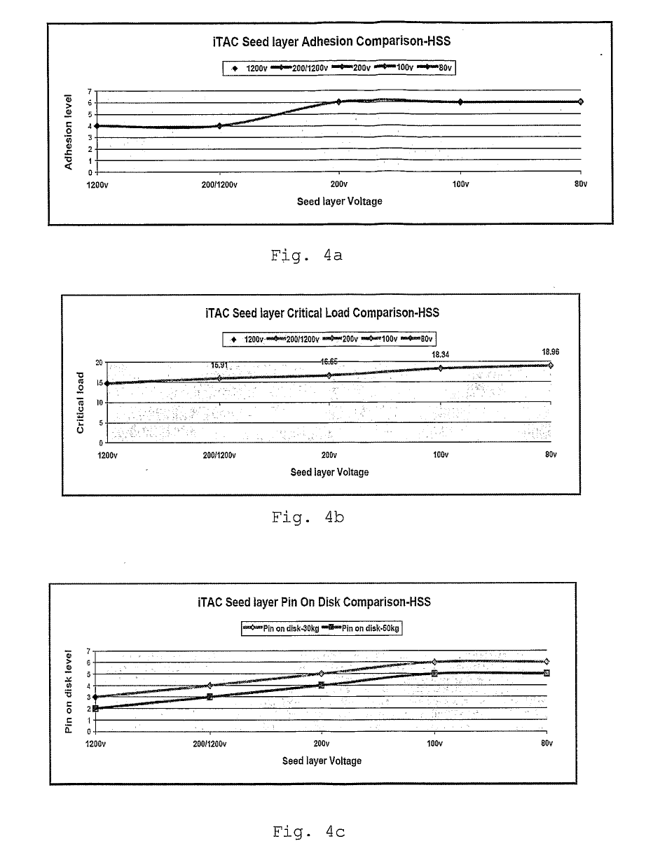

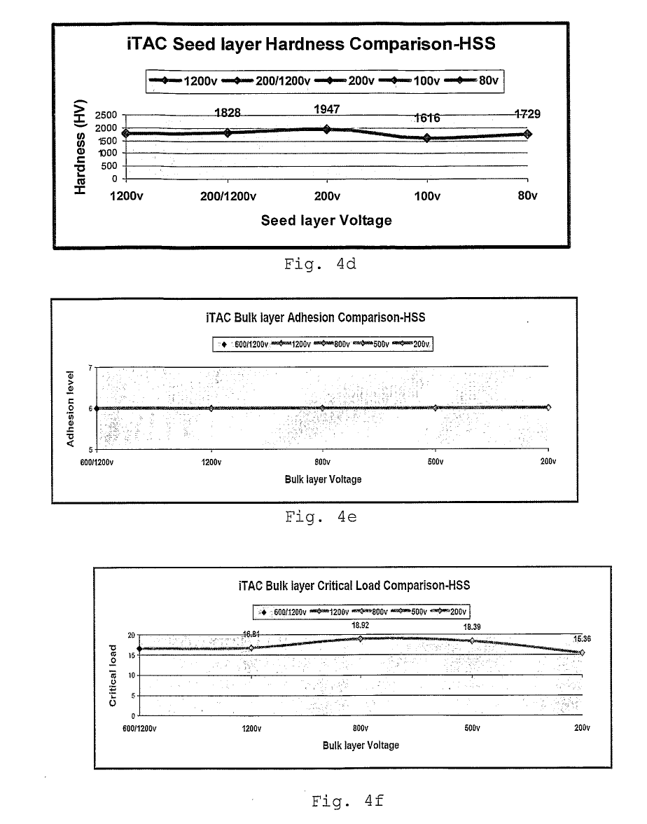

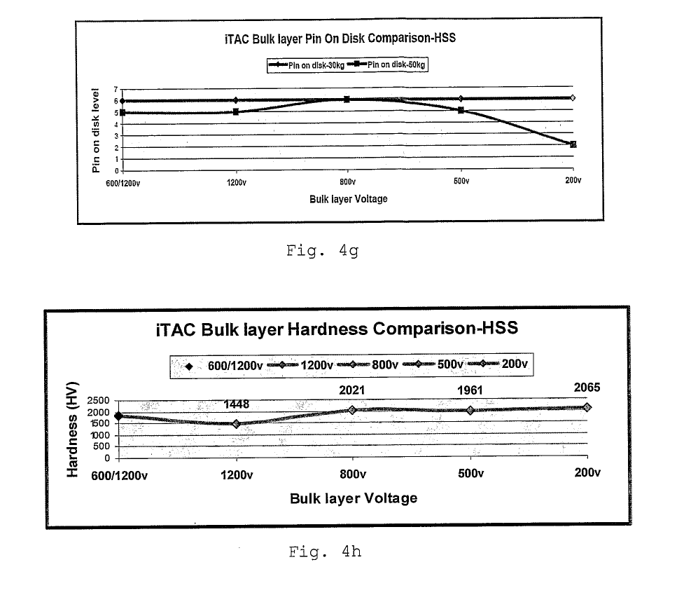

The results obtained in Table 1A are also graphically represented in FIG. 4a-4d.

From the results shown above, 120VP C1 seed layer is preferred on a HSS substrate.

The coating process then repeated by fixing the seed layer bias while adjusting the bulk layer bias. The titanium layer condition is fixed at 1000V (0.25 microns), the seed layer condition fixed at 120V (0.12 microns), the sputtered carbon layers each having thickness of 0.02 microns and FCVA carbon layers each having thickness of 0.35 microns. The results are tabulated in Table 1B.

TABLE 1B

| | | Adhesion | Pin on | Pin on | Critical | Hardness |
|---|---|---|---|---|---|---|
| Bulk layer | | level | disk-30 kg | disk-50 kg | load | (HV) |
| 600/1200 | v | 6 | 6 | 5 | 16.56 | 1829 |
| 1200 | v | 6 | 6 | 5 | 16.81 | 1448 |
| 800 | v | 6 | 6 | 6 | 18.92 | 2021 |
| 500 | v | 6 | 6 | 5 | 18.39 | 1961 |
| 200 | v | 6 | 6 | 2 | 15.36 | 2065 |

*Critical load under 100 microns diamond tip

The results obtained in Table 1B are also graphically represented in FIG. 4e-4h.

From the results shown above, 800 VP bulk layer is preferred on a HSS substrate.

### Experiment 2

### Seed Layer & Bulk Layer Comparison on Carbide Substrate

In this experiment, carbide is used as the substrate. The coating process is carried out by fixing the bulk layer bias while adjusting the seed layer bias. In the first experiment, no titanium layer is applied, the bulk layer condition fixed at 600/1200 v having sputtered carbon layers each of thickness of 0.02 microns and FCVA carbon layers each of thickness of 0.35 microns. The results are tabulated in Table 2A.

TABLE 2A

| | Adhesion | Pin on | | |
|---|---|---|---|---|
| Seed layer | level | disk-30 kg | Pin on disk-50 kg | Critical load |
| 80 v (Wo Ti) | 2 | 1 | 1 | 15.77 |
| 1000 v (Wo Ti) | 6 | 6 | 6 | 22.96 |
| 1500 v (Wo Ti) | 6 | 6 | 6 | 20.25 |

*Critical load under 100 microns diamond tip

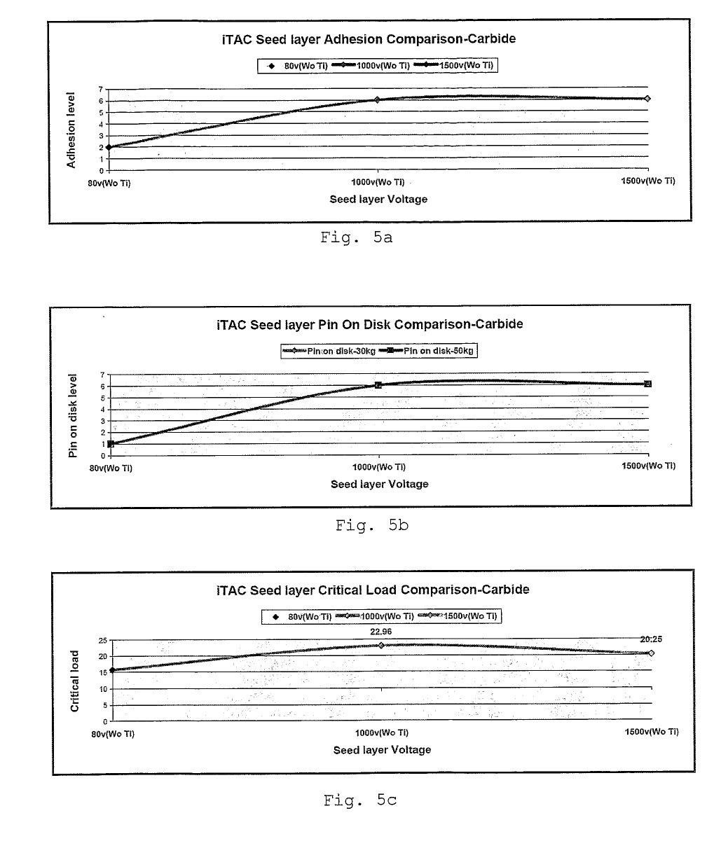

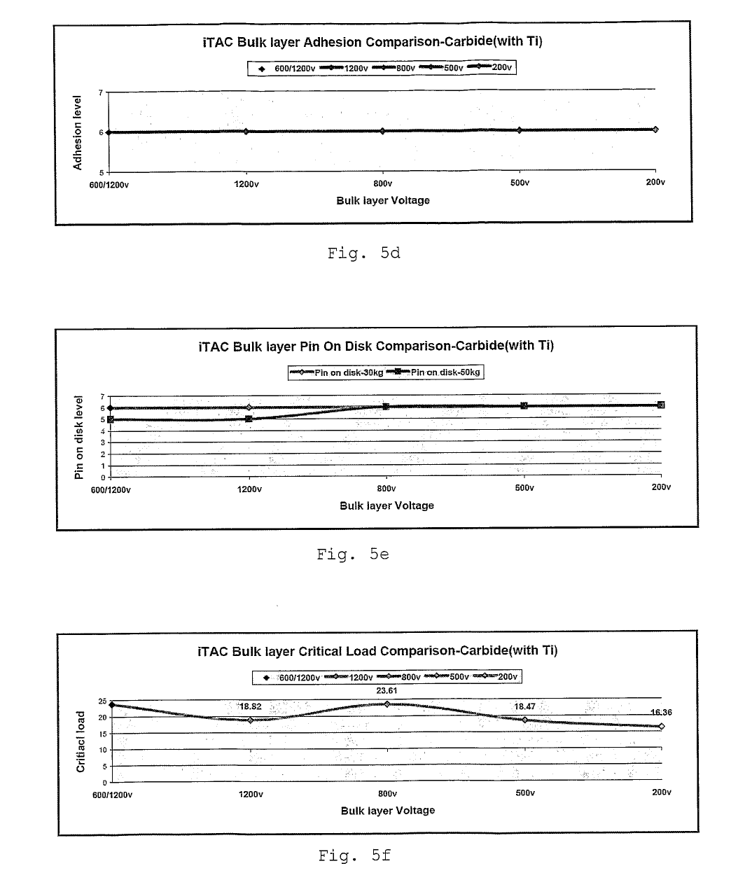

The results obtained in Table 2A are also graphically represented in FIG. 5a-5c.

From the results shown above, more than 1000 VP C1 seed layer is preferred on a carbide substrate without titanium interlayer.

The coating process then repeated by fixing the seed layer bias while adjusting the bulk layer bias. In this experiment, a titanium layer is provided. The titanium layer condition is fixed at 1000V (0.25 microns), the seed layer condition fixed at 120V (0.12 microns), the sputtered carbon layers each having thickness of 0.02 microns and FCVA carbon layers each having thickness of 0.35 microns. The results are tabulated in Table 2B.

TABLE 2B

| | | | | Pin on | Critical |
|---|---|---|---|---|---|
| Bulk layer | | Adhesion level | Pin on disk-30 kg | disk-50 kg | load |
| 600/1200 | v | 6 | 6 | 5 | 23.79 |
| 1200 | v | 6 | 6 | 5 | 18.82 |
| 800 | v | 6 | 6 | 6 | 23.61 |
| 500 | v | 6 | 6 | 6 | 18.47 |
| 200 | v | 6 | 6 | 6 | 16.36 |

*Critical load under 100 microns diamond tip

The results obtained in Table 2B are also graphically represented in FIG. 5d-5f.

From the results shown above, 800 VP bulk layer is preferred on a carbide substrate with titanium interlayer.

### Experiment 3

### Sputtered Carbon Thickness Vs Performance Comparison on High Speed Steel

In this experiment, high speed steel is used as the substrate. The coating process is carried out by fixing the bulk layer bias and the seed layer bias but varying the thickness of the sputtered carbon layer. The titanium layer condition is fixed at 1000 v (0.25 microns), the bulk layer condition fixed at 500/1200 v having FCVA carbon layers each of thickness of 0.35 microns. The seed layer is fixed at 120V (0.12 microns). The results are tabulated in Table 3A.

TABLE 3A

| SPT | Adhesion | Pin on | Pin on | Critical | Hardness |
|---|---|---|---|---|---|
| C Thickness | level | disk-30 kg | disk-50 kg | load | (HV) |
| 0.02 | 6 | 6 | 5 | 18.05 | 2128 |
| 0.01 | 6 | 6 | 5 | 21.06 | 1778 |
| 0.005 | 6 | 6 | 5 | 19.34 | 2338 |
| 0.0025 | 6 | 3 | 2 | 18.36 | 2413 |

*Critical load under 100 microns diamond tip

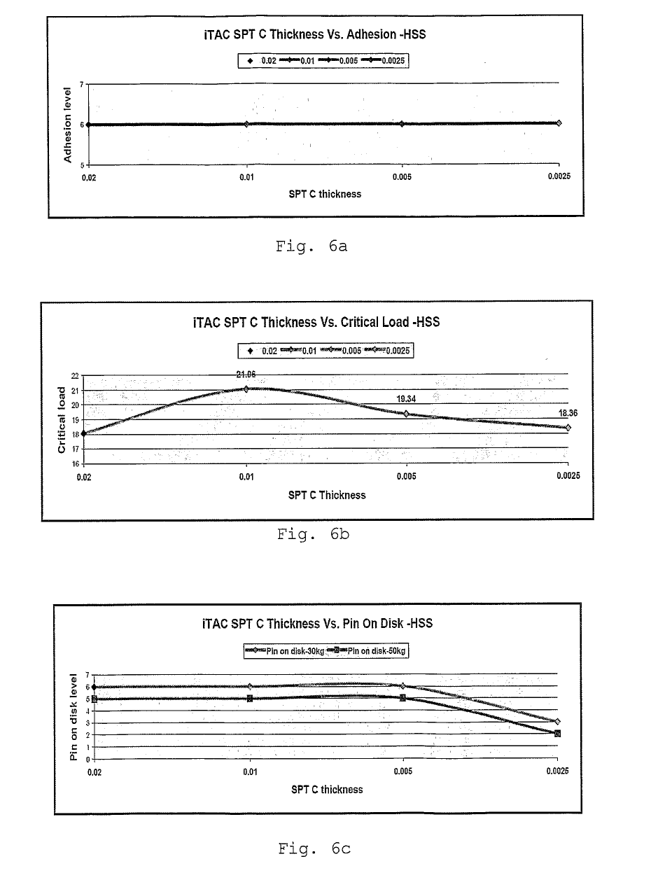

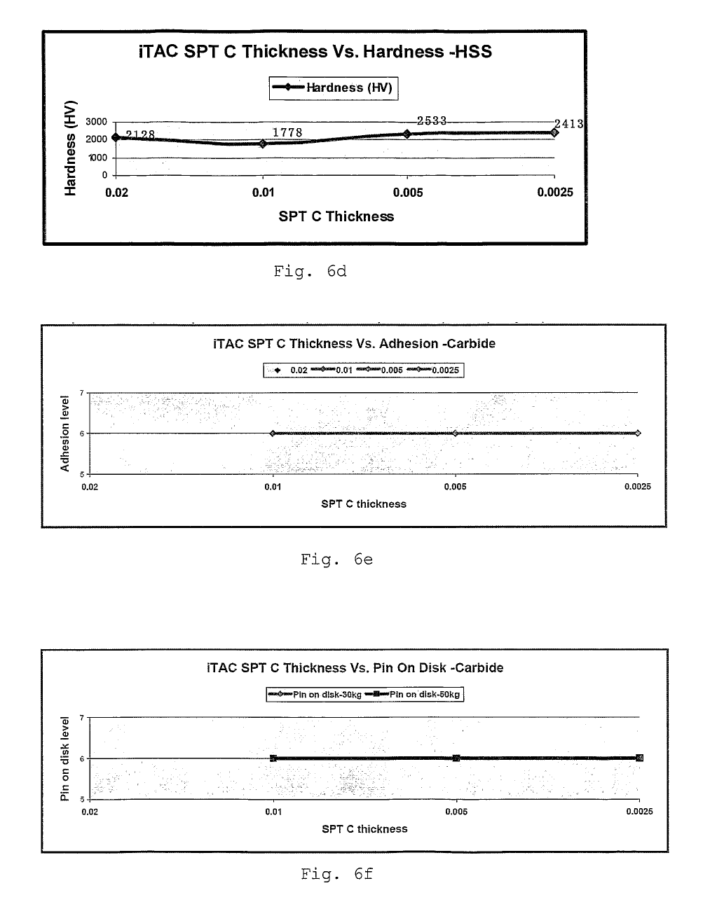

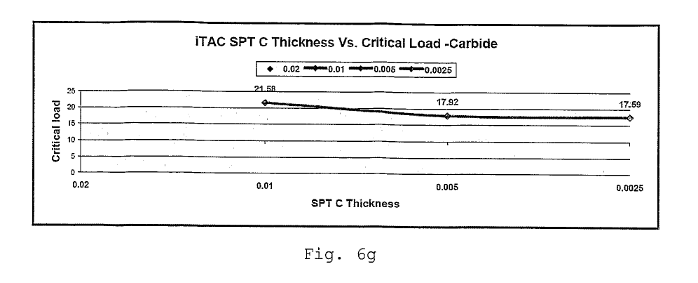

The results obtained in Table 3A are also graphically represented in FIG. 6a-6d.

From the results shown above, it can be seen that the carbon layer thickness can be selected based on what is desired of the individual properties of hardness and ability to withstand high stress etc. A thickness of less than 20 nanometers yields relatively good results.

### Experiment 4

### Sputtered Carbon Thickness VS Performance Comparison on Carbide Substrate

In this experiment, carbide is used as the substrate. The coating process is carried out by fixing the bulk layer bias and the seed layer bias but varying the thickness of the sputtered carbon layer. The titanium layer condition is fixed at 1000 v (0.25 microns), the bulk layer condition fixed at 500/1200 v having FCVA carbon layers each of thickness of 0.35 microns. The seed layer is fixed at 120V (0.12 microns). The results are tabulated in Table 3B.

TABLE 3B

| | Adhesion | Pin on | Pin on | |
|---|---|---|---|---|
| SPT C Thickness | level | disk-30 kg | disk-50 kg | Critical load |
| 0.02 | | | | |
| 0.01 | 6 | 6 | 6 | 21.58 |
| 0.005 | 6 | 6 | 6 | 17.92 |
| 0.0025 | 6 | 6 | 6 | 17.59 |

*Critical load under 100 microns diamond tip

The results obtained in Table 3B are also graphically represented in FIG. 6e-6g.

From the results shown above, it can be seen that the carbon layer thickness can be selected based on what is desired of the individual properties of hardness and ability to withstand high stress etc. A thickness of less than 20 nanometers yields relatively good results.

### Experiment 5

### FCVA Carbon Thickness VS Performance Comparison on High Speed Steel

In this experiment, high speed steel is used as the substrate. The coating process is carried out by fixing the bulk layer bias and the seed layer bias but varying the thickness of the FCVA carbon layer. The titanium layer condition is fixed at 1000 v (0.25 microns), the bulk layer condition fixed at 500/1200 v having sputtered carbon layers each of thickness of 5 nanometers. The seed layer is fixed at 120V (0.12 microns). The results are tabulated in Table 4A.

TABLE 4A

| Spacing | Adhesion | Pin on | Pin on | | Hardness |
|---|---|---|---|---|---|
| Thickness | level | disk-30 kg | disk-50 kg | Critical load | (HV) |
| 0.35 | 6 | 6 | 5 | 19.34 | 2338 |
| 0.45 | 6 | 6 | 5 | 20.57 | 2378 |
| 0.650 | 6 | 6 | 5 | 16.24 | 2533 |

*Critical load under 100 microns diamond tip

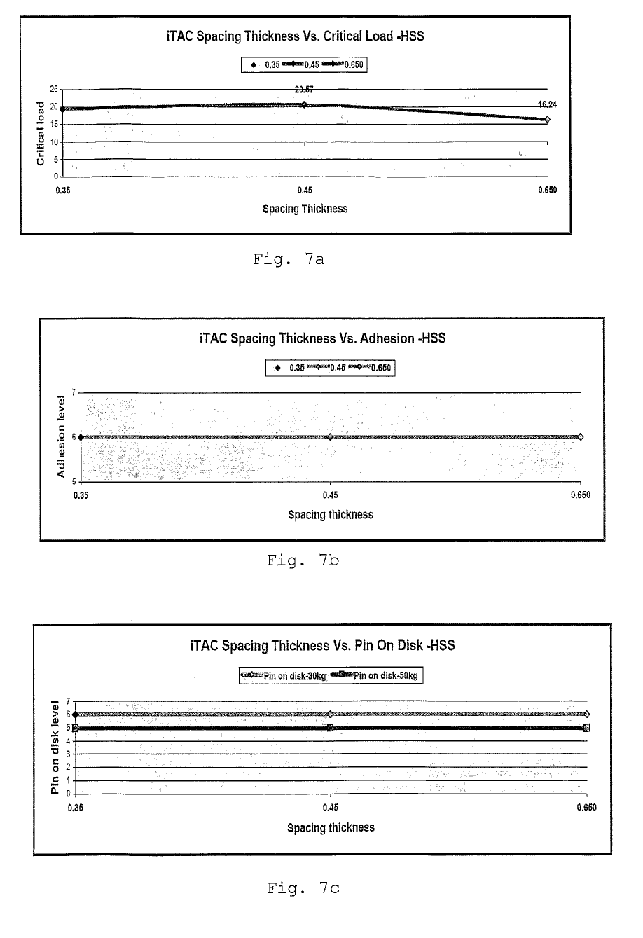

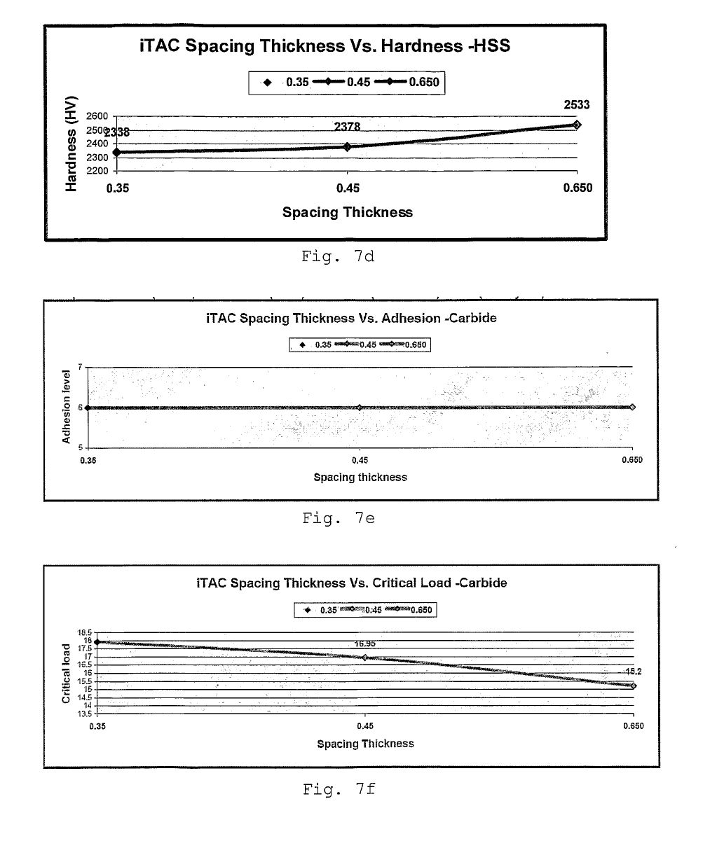

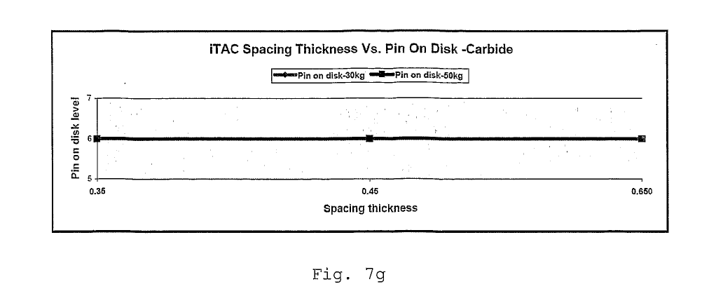

The results obtained in Table 4A are also graphically represented in FIG. 7a-7d.

From the results shown above, it can be seen that the FCVA layer thickness can be selected based on what is desired of the individual properties of hardness and ability to withstand high stress etc. A thickness of more than 0.35 microns yield relatively good results.

### Experiment 6

### FCVA Carbon Thickness VS Performance Comparison on Carbide Substrate

In this experiment, carbide is used as the substrate. The coating process is carried out by fixing the bulk layer bias and the seed layer bias but varying the thickness of the FCVA carbon layer. The titanium layer condition is fixed at 1000 v (0.25 microns), the bulk layer condition fixed at 500/1200 v having sputtered carbon layers each of thickness of 5 nanometers. The seed layer is fixed at 120V (0.12 microns). The results are tabulated in Table 4B.

TABLE 4B

| Spacing | Adhesion | Pin on | | |
|---|---|---|---|---|
| Thickness | level | disk-30 kg | Pin on disk-50 kg | Critical load |
| 0.35 | 6 | 6 | 6 | 17.92 |
| 0.45 | 6 | 6 | 6 | 16.95 |
| 0.650 | 6 | 6 | 6 | 15.2 |

*Critical load under 100 microns diamond tip

The results obtained in Table 4B are also graphically represented in FIG. 7e-7g.

From the results shown above, it can be seen that the FCVA layer thickness can be selected based on what is desired of the individual properties of hardness and ability to withstand high stress etc. A thickness of more than 0.35 microns yield relatively good results.

### Comparative Example

In this example, a first substrate was TA-C coated using conventional coating methods (such as cathodic vacuum arc deposition) used in the industry. A second substrate was coated using the methods disclosed herein. The stress level of both substrates were measured and it was found that for the same overall thickness of coating, the conventionally coated first substrate has a stress level of more than 1 GPa, whereas the substrate coated with the methods disclosed herein has a stress level of less than 0.2 GPa. As the stress level of the second substrate is significantly lesser than that of the conventionally first coated substrate, it could be extrapolated that the second substrate is less brittle than the conventionally coated first substrate.

### Applications

The presently disclosed method is an effective method of coating a substrate to produce a coating which has superior hardness as well as has good resistance to wear and tear.

Advantageously, the coating disclosed herein is which is achievable by the disclosed method is capable of resisting high impact stresses that are encountered in heavy duty applications. When these coatings are utilized in automobile components which are subjected to harsh conditions, the components have improved resistance to scratching and deformation.

More advantageously, the disclosed method can produce relatively thick coatings (for example more than 20 microns) on a substrate which have good adhesion to substrate surfaces as well as high density and improved strength. Even more advantageously, when the coatings are applied to automobile components which have abrasive functionalities, the lifespan of such components are effectively prolonged.

The coatings produced by the methods disclosed herein are also less brittle and less prone to cracking and breakage as compared to conventional TAC coatings. Due to the low brittleness and reduced likelihood of breakage, the thickness of the coating can be made to be thicker than conventional TAC coatings. Advantageously, these thick coatings do not wear of easily even when they are subjected to highly abrasive conditions such as in the automobiles. As a result, there is no need to constantly recoat the substrate in order to upkeep its protective functions and hardness. From an economical perspective, this reduces the need for repeated coating and thus saves costs.

In addition, as the presently disclosed method of coating utilizes a hybrid of physical deposition methods, the advantages inherent in each of the deposition methods are compounded and the certain disadvantages present in either of the individual methods alone are ameliorated.

Advantageously, the steps involved in the presently disclosed method are undertaken at low temperatures of about 100° C. This reduces the likelihood of deformation of the substrate by reducing the thermal stresses that are present within the substrates. Consequently, as low temperature can be employed in the disclosed method, the productivity of the process on an industrial scale improves substantially. More advantageously, because there is no longer a need to maintain the process in a high temperature environment, a large amount of energy is saved and this reduces the overall operating costs.

While reasonable efforts have been employed to describe equivalent embodiments of the present invention, it will be apparent to the person skilled in the art after reading the foregoing disclosure, that various other modifications and adaptations of the invention may be made therein without departing from the spirit and scope of the invention and it is intended that all such modifications and adaptations come within the scope of the appended claims.

1. A method of depositing a coating on a substrate, the method comprising the steps of:
(a) depositing material on a substrate by performing a cathodic vacuum arc (CVA) deposition step; and
(b) depositing material on a substrate by performing a physical vapor deposition (PVD) step that excludes CVA deposition,
wherein the thickness of the material deposited in step (a) is greater than the thickness of material deposited in step (b).

2. The method as claimed in claim 1, wherein said step (a) comprises filtering the CVA to thereby perform a filtered cathodic vacuum arc deposition (FCVA) step.

3. The method as claimed in claim 1 or claim 2, wherein said step (b) comprises a sputtering deposition step.

4. The method as claimed in claim 1, further comprising the step of repeating alternating steps of (a) and (b) to form subsequent layers.

5. The method as claimed in claim 2, wherein the pressure in the vacuum chamber during the FCVA deposition in step (a) is lower than the pressure in the vacuum chamber during the PVD in step (b).

6. The method as claimed in claim 5, the pressure in the vacuum chamber during the FCVA deposition in step (a) is less than 1 mTorr and the pressure in the vacuum chamber during the PVD in step (b) is more than 1 mTorr.

7. The method as claimed in claim 1, wherein said material in at least one of steps (a) and (b) comprises at least one of a metal, metal compound and carbon.

8. The method of claim 7, wherein said metal is a hard metal.

9. The method as claimed in claim 7, wherein said metal compound is at least one of a metal oxide, a metal carbide, a metal nitride, a metal carbon nitride, a metal silicide and a hard metal boride.

10. The method as claimed in claim 2, wherein said FCVA deposition layer is deposited directly on said substrate.

11. The method as claimed in claim 3, wherein said sputtering step deposits a material layer of thickness less than 50 nm.

12. The method as claimed in claim 3, wherein said FCVA step deposits a material layer of thickness more than 50 nm.

13. The method as claimed in claim 3, wherein the FCVA step deposits a material layer having a thickness dimension which is greater than the thickness dimension of the material layer deposited by the sputtering step in the range of 2 to 100 times.

14. The method as claimed in claim 4, wherein the total thickness of the coating is more than 1 micron.

15. The method as claimed in claim 4, wherein the material deposited by said FCVA step and said sputtering step comprises carbon.

16. The method as claimed in claim 15, wherein the carbon layer deposited by the FCVA step is harder relative to the carbon layer deposited by the sputtering step.

17. The method as claimed in claim 16, wherein the carbon layer deposited by the FCVA step is tetrahedral amorphous carbon and the carbon layer deposited by the sputtering step is amorphous carbon.

18. The method as claimed in any one of the preceding claims wherein the substrate is an automobile component.

19. The method as claimed in claim 18, wherein the automobile component is selected from the group consisting of a piston ring, a piston pin, a cam shaft, a lift valve and an injection nozzle.

20. A piston ring or a piston pin coated by the method as claimed in any one of claims 1 to 19.

21. A substrate having a coating with at least two layers, one of the layers having been deposited by physical vapor deposition (PVD) that excludes cathodic vapor arc deposition (CVA) and having less stress relative to the other layer that has been deposited by cathodic vapor arc deposition (CVA), wherein the thickness of the material deposited by CVA is greater than the thickness of material deposited by PVD that excludes CVA.

22. A coating comprising an intermediate carbon layer that is disposed between a base carbon and upper carbon layer, wherein the intermediate carbon layer has less stress relative to the base and upper carbon layers, wherein the thickness of the intermediate carbon layer is less than the thickness of the upper and base carbon layers.

23. A coating as claimed in claim 22, wherein the intermediate carbon layer is amorphous carbon and the base and upper layers are tetrahedral amorphous carbon layers.

24. A coating as claimed in claim 22 or claim 23, wherein the base carbon and upper carbon layer each have a stress of more than 1 GPa.

25. A coating as claimed in any one of claims 22 to 24, wherein the intermediate carbon layer exhibits a stress that is at least 20% less than the stress of at least one of the base carbon layer and the upper carbon layer.

26. A coating as claimed in any one of claims 22 to 25, wherein the coating has a hardness of at least 10 GPa.

27. A coating as claimed in any one of claims 22 to 26, wherein the thickness of the base and upper carbon layer is greater than the thickness of the intermediate layer by a factor of 2 to 100 times.

28. A coating as claimed in any one of claims 22 to 27, wherein the intermediate carbon layer is deposited by physical vapor deposition (PVD) that excludes cathodic vapor arc deposition (CVA) while the base and upper carbon layers are deposited by CVA.

29. A coating as claimed in claim 28, wherein the intermediate carbon layer is deposited by sputtering while the base and upper carbon layers are deposited by FCVA.

30. An automobile component having a coating as defined in any one of claims 22 to 29.

31. An automobile component as claimed in claim 30, selected from the group consisting of a piston ring, a piston pin, a cam shaft, a lift valve and an injection nozzle.
